(19) United States
(12) Patent Application Publication
(10) Pub. No.: US 2025/0356913 A1
(43) Pub. Date: Nov. 20, 2025

(54) WRITE ASSIST CIRCUIT AND STATIC RANDOM ACCESS MEMORY

(71) Applicant: Fujitsu Limited, Kawasaki-shi (JP)

(72) Inventor: Kensuke SHINOHARA, Kawasaki (JP)

(73) Assignee: Fujitsu Limited, Kawasaki-shi (JP)

(21) Appl. No.: 19/204,741

(22) Filed: May 12, 2025

(30) Foreign Application Priority Data
May 16, 2024 (JP) 2024-080164

(51) Int. Cl. G11C 11/419

(52) U.S. Cl. CPC G11C 11/419

(57) ABSTRACT

A write assist circuit for a static random access memory includes a first wiring, a plurality of second wirings (victim wires) that receive noise in the negative potential direction from the first wiring, and a selection circuit. The selection circuit selects the first number of second wirings from the plurality of second wirings in response to an input selection signal and outputs a potential of a negative potential magnitude based on negative potentials applied to the first number of second wirings due to the noise.

### CROSS-REFERENCE TO RELATED APPLICATION

This application is based upon and claims the benefit of priority of the prior Japanese Patent Application No. 2024-080164, filed on May 16, 2024, the entire contents of which are incorporated herein by reference.

### FIELD

The embodiments discussed herein relate to a write assist circuit and a static random access memory (SRAM).

### BACKGROUND

As miniaturization increases in semiconductor technology, manufacturing variations become more significant, which leads to greater variations in transistor characteristics and wiring resistance and capacitance. In addition, the use of artificial intelligence (AI) and big data in industry has advanced. In order to ensure computing power for AI and processing a huge amount of data including big data, the operating voltage of semiconductor integrated circuits such as processors is being reduced.

SRAM is sometimes used as cache memory for processors. As manufacturing variations increase and operating voltage decreases, the write performance of SRAM memory cells may deteriorate. In order to mitigate this deterioration in the write performance, a write assist circuit that expands an operation margin for writing to memory cells may be used (see, for example, Japanese Laid-open Patent Publication No. 2021-140848 and International Publication Pamphlet No. WO 2014/149093).

One of assist methods for write assist circuits is a negative bit line (NBL) method, in which the potentials of bit lines are lowered to negative potentials to assist writing to memory cells. For example, there is an NBL-based write assist circuit in which the assist amount is adjustable using a capacitive element. There is also another NBL-based write assist circuit that uses inter-wire capacitance that is parasitic capacitance, instead of a capacitive element, in order to prevent an increase in area.

### SUMMARY

In one aspect, there is provided a write assist circuit for a static random access memory, the write assist circuit including: a first wiring; a plurality of second wirings configured to receive noise in a negative potential direction from the first wiring; and a selection circuit configured to select a first number of second wirings from the plurality of second wirings in response to an input selection signal and output a potential of a negative potential magnitude based on a negative potential applied to the first number of second wirings due to the noise.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates the configuration of part of an SRAM according to a first embodiment;

FIG. 2 illustrates an example of the relationship between the number of selected victim wires and the negative potential magnitude;

FIG. 3 illustrates an SRAM according to a comparative example;

FIG. 4 is a timing chart illustrating an example of temporal changes in the potentials of various parts during a write operation in the SRAM of the comparative example;

FIG. 5 illustrates an example of the overall configuration of an SRAM according to a second embodiment;

FIG. 6 illustrates an example of the configuration of a write assist circuit according to the second embodiment;

FIG. 7 illustrates an example of changes in the potential of each victim wire during a write assist operation in the case where a shorting circuit is not provided;

FIG. 8 illustrates an example of temporal changes in the potentials of bit lines in response to the value of a selection signal SW[2:0];

FIG. 9 illustrates an example of a test system;

FIG. 10 is a flowchart illustrating an example flow of a process of adjusting the selection signal SW[2:0];

FIG. 11 illustrates an example of data held in a shift register that generates the selection signal SW[2:0];

FIG. 12 illustrates an SRAM according to a first modification; and FIG. 13 illustrates an SRAM according to a second modification.

### DESCRIPTION OF EMBODIMENTS

A conventional NBL-based write assist circuit that uses inter-wire capacitance has a fixed assist amount. Therefore, the assist amount is not adjustable to an appropriate amount even if the manufacturing variations deviate from an expected range or specification changes occur after SRAM manufacturing.

Hereinafter, embodiments will be described with reference to the drawings.

### First Embodiment

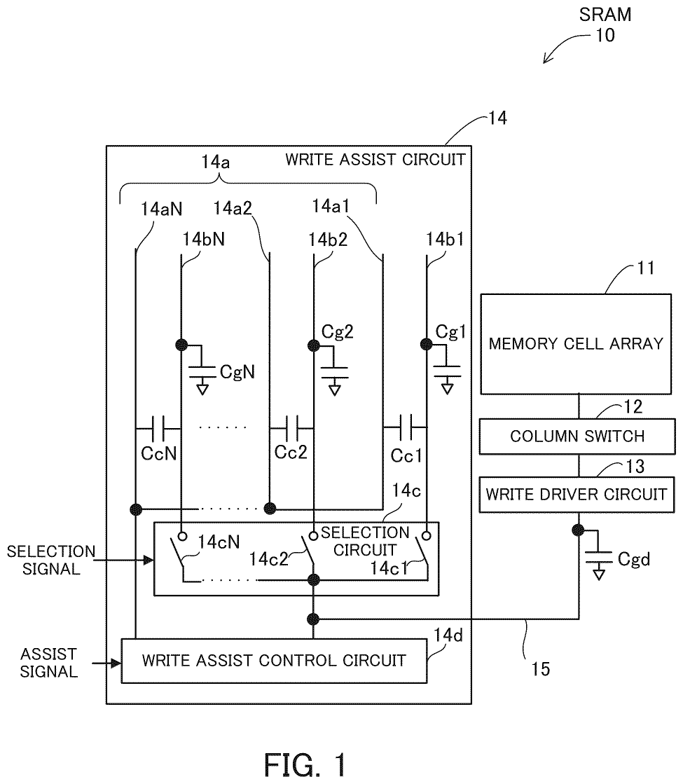

FIG. 1 illustrates the configuration of part of an SRAM according to a first embodiment.

The SRAM 10 includes a memory cell array 11, a column switch 12, a write driver circuit 13, and a write assist circuit 14. In FIG. 1, a decoder that decodes an address signal, a timing control circuit that controls operation timing of each unit, an input/output circuit, a circuit that performs operations related to reading, and others are not illustrated.

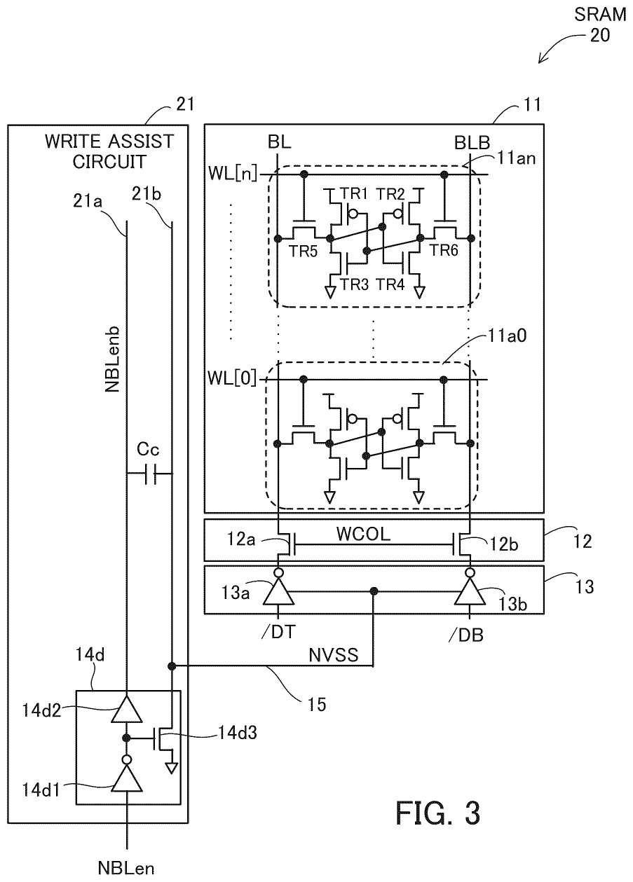

The memory cell array 11 includes a plurality of memory cells arranged in an array. Each memory cell is connected to a word line and two bit lines (hereinafter, also referred to as a bit line pair). A specific example of the memory cell array 11 will be described later (see FIG. 3).

The column switch 12 selects any bit line pair of the memory cell array 11 in response to a column selection signal supplied from the decoder.

The write driver circuit 13 applies a potential corresponding to write data to the selected bit line pair based on a timing signal output from the timing control circuit. Different potentials are applied to the first bit line and the second bit line included in the bit line pair. For example, when a potential at a high (H) logic level is applied to the first bit line, a potential at a low (L) logic level is applied to the second bit line. When a potential at an L logic level is applied to the first bit line, a potential at an H logic level is applied to the second bit line. The bit line pair of the first bit line and the second bit line may be referred to as a complementary bit line pair. The H-level potential corresponds to write data “1,” and the L-level potential corresponds to write data “0.”

The write assist circuit 14 expands an operation margin (the potential difference between the first bit line and the second bit line) for writing to memory cells in order to prevent a deterioration in write performance caused by manufacturing variations, reduced operating voltage, and others.

The write assist circuit 14 includes a first wiring 14a, second wirings (hereinafter referred to as victim wires) 14b1, 14b2, . . . , and 14bN, a selection circuit 14c, and a write assist control circuit 14d.

The first wiring 14a is connected to the write assist control circuit 14d. When the write assist is executed, the potential of the first wiring 14a is changed from an H-level potential to an L-level potential by the write assist control circuit 14d.

In the example of FIG. 1, the first wiring 14a includes a plurality of wiring parts (hereinafter, referred to as aggressor wires) 14a1, 14a2, . . . , and 14aN arranged in the same direction as the wiring direction of the victim wires 14b1 to 14bN. Each of the aggressor wires 14a1 to 14aN is arranged adjacent to one of the victim wires 14b1 to 14bN at a shorter distance than to the other victim wires. This equalizes the inter-wire capacitance between adjacent wires across all adjacent wire pairs, which in turn improves the adjustment accuracy of the assist amount.

The victim wires 14b1 to 14bN receive noise in the negative potential direction based on the magnitudes of the inter-wire capacitances from the first wiring 14a. In the example of FIG. 1, inter-wire capacitances Cc1, Cc2, . . . , and CcN are illustrated. The inter-wire capacitance Cc1 is the inter-wire capacitance between the aggressor wire 14a1 and the victim wire 14b1. The inter-wire capacitance Cc2 is the inter-wire capacitance between the aggressor wire 14a2 and the victim wire 14b2. The inter-wire capacitance CcN is the inter-wire capacitance between the aggressor wire 14aN and the victim wire 14bN.

FIG. 1 also illustrates ground capacitances Cg1, Cg2, . . . , and CgN, which are parasitic capacitances connected to the victim wires 14b1 to 14bN, respectively.

The selection circuit 14c selects the first number of victim wires from the victim wires 14b1 to 14bN in response to an input selection signal. Then, the selection circuit 14c outputs a potential of a negative potential magnitude based on negative potentials applied to the first number of victim wires due to the noise. The first number is determined by the value of the selection signal, and is referred to as a selection number in the following description. The selection number is an integer of 0 or more. The reason why the selection number includes 0 is that there is a case where the write assist is not needed depending on the quality of the manufactured SRAM 10. The selection signal is input from the outside of the SRAM 10, for example.

The selection circuit 14c is implemented by using switches 14c1, 14c2, . . . , and 14cN as illustrated in FIG. 1. In the selection circuit 14c, one or more of the switches 14c1 to 14cN are turned on according to the selection signal, so that as many victim wires as specified by the selection number, among the victim wires 14b1 to 14bN, are electrically connected to the write driver circuit 13. These victim wires, the number of which is specified by the selection number, are electrically connected to the low-potential power supply terminal of the write driver circuit 13. The low-potential power supply terminal of the write driver circuit 13 is, for example, a power supply terminal to which a ground potential VSS (for example, 0 V) is applied while the assist operation is not performed.

The write assist control circuit 14d receives an assist signal for instructing the execution of the write assist from the timing control circuit. Upon receiving the assist signal, the write assist control circuit 14d changes the potentials of the aggressor wires 14a1 to 14aN from the H level to the L level.

In addition, upon receiving the assist signal, the write assist control circuit 14d enables the electrical connection between the write driver circuit 13 and the selection circuit 14c. FIG. 1 illustrates a ground capacitance Cgd of a wire 15 connecting the write driver circuit 13 and the write assist circuit 14.

Next, an operation example of the write assist by the write assist circuit 14 of the first embodiment will be described.

When data is written to the memory cell array 11, the write assist control circuit 14d brings the victim wires 14b1 to 14bN and the wire 15 into a floating state at the timing when the assist signal is input.

Further, the write assist control circuit 14d changes the potentials of the aggressor wires 14a1 to 14aN from the H level to the L level. As a result, the victim wires 14b1 to 14bN receive noise in the negative potential direction based on the magnitudes of the inter-wire capacitances Cc1 to CcN from the aggressor wires 14a1 to 14aN, and are brought to negative potentials.

In the case where the selection circuit 14c selects victim wires in response to an input selection signal, the negative potentials applied to the selected victim wires are transmitted to the wire 15. The negative potential magnitude of the potential of the wire 15 corresponds to the assist amount.

The negative potential magnitude ΔVneg is expressed as the following Equation (1):

ΔVneg=−(CcN+ . . . +Cc2+Cc1)/(CcN+ . . . +Cc2+Cc1+CgN+ . . . +Cg2+Cg1+Cgd)×VDD (1),

where Cc1 to CcN denote the magnitudes of the inter-wire capacitances Cc1 to CcN, Cg1 to CgN and Cgd denote the magnitudes of the ground capacitances Cg1 to CgN and Cgd, and VDD denotes the power supply potential on the high potential side.

If Cc1 to CcN have the same value (=Cc) and Cg1 to CgN have the same value (=Cg), Equation (1) is expressed as the following Equation (2).

ΔVneg=−N×Cc/(N×Cc+N×Cg+Cgd)×VDD (2)

Equation (2) represents the negative potential magnitude in the case where all of the N victim wires 14b1 to 14bN are selected. If the number of selected victim wires is denoted by n instead of N, the relationship between the number of selected victim wires and the negative potential magnitude is represented based on Equation (2), for example, as follows.

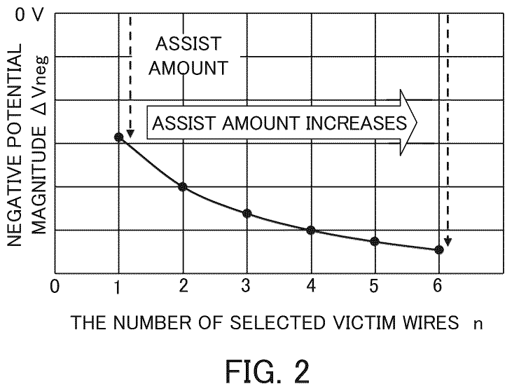

FIG. 2 illustrates an example of the relationship between the number of selected victim wires and the negative potential magnitude. The horizontal axis represents the number of selected victim wires (n), and the vertical axis represents the negative potential magnitude (ΔVneg).

As illustrated in FIG. 2, when the number of selected victim wires is increased according to a selection signal, the negative potential magnitude, that is, the assist amount increases. Conversely, when the number of selected victim wires is decreased according to the selection signal, the assist amount decreases.

Hereinafter, a comparative example will be specifically described, which provides a write assist circuit using the inter-wire capacitance between a pair of an aggressor wire and a victim wire, and a problem thereof.

### COMPARATIVE EXAMPLE

FIG. 3 illustrates an SRAM according to a comparative example. In FIG. 3, the same elements as those illustrated in FIG. 1 are denoted by the same reference numerals.

In the SRAM 20 according to the comparative example, a write assist circuit 21 includes an aggressor wire 21a, a victim wire 21b, and a write assist control circuit 14d.

The aggressor wire 21a and the victim wire 21b are connected to the write assist control circuit 14d. An inter-wire capacitance Cc, which is parasitic capacitance, is the inter-wire capacitance between the aggressor wire 21a and the victim wire 21b. In FIG. 3, the potential of the aggressor wire 21a is denoted as “NBLenb.”

FIG. 3 illustrates an example of the configuration of the write assist control circuit 14d, which is also illustrated in FIG. 1. The write assist control circuit 14d includes an inverter circuit 14d1, a buffer circuit 14d2, and a transistor 14d3.

An enable signal NBLen is input to the inverter circuit 14d1 from, for example, a timing control circuit, which is not illustrated. When the potential of the enable signal NBLen is at H level, the enable signal NBLen corresponds to the above-described assist signal.

The output signal of the inverter circuit 14d1 is input to the buffer circuit 14d2. The output potential of the buffer circuit 14d2 serves as the potential NBLenb of the aggressor wire 21a.

The transistor 14d3 has a switching function of switching between enabling and disabling the electrical connection between the write driver circuit 13 and the victim wire 21b. In the example of FIG. 3, the transistor 14d3 is an n-channel metal-oxide-semiconductor field-effect transistor (MOSFET). The output signal of the inverter circuit 14d1 is input to the gate of the transistor 14d3. The drain of the transistor 14d3 is electrically connected to the victim wire 21b and the low-potential power supply terminal of the write driver circuit 13. The source of the transistor 14d3 is grounded.

FIG. 3 illustrates an example of the configuration of a memory cell array 11, a column switch 12, and a write driver circuit 13, which are also illustrated in FIG. 1.

The memory cell array 11 includes memory cells 11a0 to 11an, bit lines BL and BLB, and word lines WL[0] to WL[n]. The memory cells 11a0 to 11an are connected to bit lines BL and BLB. The memory cell 11a0 is connected to the word line WL[0]. The memory cell 11an is connected to the word line WL[n]. The word lines WL[0] to WL[n] are connected to a decoder, which is not illustrated.

For example, when write data is written to the memory cell 11a0, the potential of the word line WL[0] becomes H level. When write data is written to the memory cell 11an, the word line WL[n] becomes H level.

FIG. 3 illustrates an example of the configuration of the memory cells 11a0 and 11an. Hereinafter, the memory cell 11an will be described as an example, but the other memory cells are implemented with the same configuration. The memory cell 11an includes transistors TR1, TR2, TR3, TR4, TR5, and TR6. In the example of FIG. 3, the transistors TR1 and TR2 are p-channel MOSFETS. The transistors TR3 to TR6 are n-channel MOSFETS.

A power supply potential is applied to the sources of the transistors TR1 and TR2. The drain of the transistor TR1 is connected to the drain of the transistor TR3, the gates of the transistors TR2 and TR4, and one of the drain and the source of the transistor TR5. The drain of the transistor TR2 is connected to the drain of the transistor TR4, the gates of the transistors TR1 and TR3, and one of the drain and the source of the transistor TR6. The gates of the transistors TR1 and TR3 are connected to each other, and the gates of the transistors TR2 and TR4 are also connected to each other. The sources of the transistors TR3 and TR4 are grounded.

The other of the drain and the source of the transistor TR5 is connected to the bit line BL. The other of the drain and the source of the transistor TR6 is connected to the bit line BLB. The gates of the transistors TR5 and TR6 are connected to the word line WL[n]. The transistors TR5 and TR6 may be referred to as transfer gates.

The column switch 12 includes transistors 12a and 12b. The write driver circuit 13 includes inverter circuits 13a and 13b. In the example of FIG. 3, the transistors 12a and 12b are n-channel MOSFETs. One of the drain and the source of the transistor 12a is connected to the bit line BL, and the other of the drain and the source thereof is connected to the output terminal of the inverter circuit 13a. One of the drain and the source of the transistor 12b is connected to the bit line BLB, and the other of the drain and the source thereof is connected to the output terminal of the inverter circuit 13b. The gates of the transistors 12a and 12b are connected to each other, and a column selection signal WCOL is applied thereto from a decoder, which is not illustrated.

Of complementary write data /DT and /DB, the write data /DT is input to the inverter circuit 13a. Of the complementary write data /DT and /DB, the write data /DB is input to the inverter circuit 13b. The low-potential power supply terminals of the inverter circuits 13a and 13b, which correspond to the low-potential power supply terminal of the write driver circuit 13, are connected to the write assist circuit 21.

In FIG. 3, the potential of a wire 15 connecting the low-potential power supply terminals of the inverter circuits 13a and 13b and the write assist circuit 21 is denoted as “NVSS.”

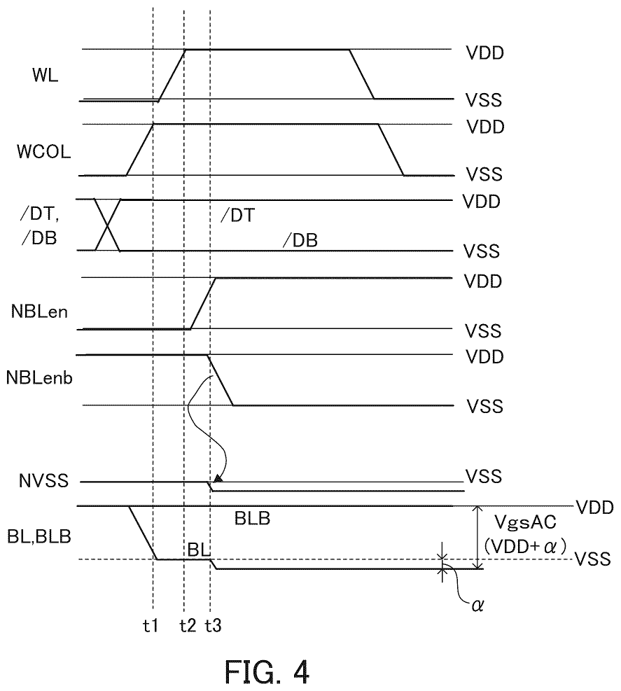

FIG. 4 is a timing chart illustrating an example of temporal changes in the potentials of various parts during a write operation in the SRAM of the comparative example. FIG. 4 illustrates temporal changes in the potential of the word line WL, which is one of the word lines WL[0] to WL[n] illustrated in FIG. 3, the potential of the column selection signal WCOL, the potentials of the write data /DT and /DB, and the potential of the enable signal NBLen. FIG. 4 also illustrates temporal changes in the potential NBLenb of the aggressor wire 21a, the potential NVSS of the wire 15, and the potentials of the bit lines BL and BLB.

When the potential of the column selection signal WCOL increases from an L level (ground potential VSS) to an H level (power supply potential VDD) (timing t1), the potentials of the write data /DT and /DB are transmitted to the bit lines BL and BLB. In the example of FIG. 4, the potential of the bit line BL is at L level, and the potential of the bit line BLB is at H level.

When the potential of the word line WL increases from the L level to the H level (timing t2), the memory cell connected to the word line WL is selected. For example, when the memory cell 11an illustrated in FIG. 3 is selected, the transistors TR5 and TR6 are turned on. Thereby, the writing of the write data /DT and /DB to the memory cell 11an starts.

When the enable signal NBLen increases from the L level to the H level (timing t3), the write assist starts. The potential NBLenb of the aggressor wire 21a decreases from the H level to the L level, and the victim wire 21b receives noise in the negative potential direction based on the magnitude of the inter-wire capacitance Cc from the aggressor wire 21a and is brought to a negative potential. As a result, the potential NVSS of the wire 15 decreases below the ground potential VSS (for example, 0 V) and becomes negative.

When the potential NVSS of the wire 15 becomes the negative potential, the potential of the bit line BL also decreases to a negative potential by a magnitude x that is a negative potential magnitude based on the magnitude of the inter-wire capacitance. As a result, the gate-source potential VgsAC of the transfer gate (for example, the transistor TR5 in FIG. 3) of the memory cell increases by the magnitude α. The increase in the gate-source potential VgsAC increases the driving force of the transfer gate and thus improves the writing performance of the memory cell.

However, the write assist circuit 21 of the comparative example has a fixed assist amount (negative potential magnitude). Therefore, the assist amount is not adjustable to an appropriate amount even if the manufacturing variations deviate from an expected range or specification changes occur after the manufacturing of the SRAM 20. In this case, for example, the following problems may occur.

In the manufactured SRAM 20, if the transistor performance is lower than expected or the magnitude of the inter-wire capacitance is smaller than expected, an expected assist amount is not sufficient, which may cause a writing error. Therefore, the yield may decrease.

If the operating voltage needs to be increased due to a change in the specifications of the SRAM 20 after manufacturing, a situation may occur in which the assist amount is desired to be set to 0 or reduced from the viewpoint of reliability. However, the write assist circuit 21 of the comparative example has a fixed assist amount. Even if such a situation occurs, it is not possible to cope with the situation. Therefore, the yield may decrease.

Even if the assist amount is excessive in view of the quality of the SRAM 20 after manufacturing, it is impossible to reduce the assist amount. Therefore, power may be wastefully consumed.

In contrast to the write assist circuit 21 of the comparative example, the write assist circuit 14 of the first embodiment is able to adjust the assist amount even after manufacturing.

More specifically, the write assist circuit 14 includes the first wiring 14a, the victim wires 14b1 to 14bN that receive noise in the negative potential direction from the first wiring 14a, and the selection circuit 14c. The selection circuit 14c selects the first number of victim wires from the victim wires 14b1 to 14bN in response to an input selection signal, and outputs a potential of a negative potential magnitude based on negative potentials applied to the selected victim wires due to the noise.

With this configuration, the SRAM 10 has the assist amount that is adjustable using the selection signal even after manufacturing. Therefore, it is possible to appropriately adjust the assist amount of the write assist circuit 14 on the basis of the quality of the SRAM 10 after manufacturing.

In addition, the write assist circuit 14 does not adjust the assist amount using an actual capacitive element. In the case of a write assist circuit that adjusts the assist amount using a capacitive element, the area increases in order to accommodate variations in the adjustment and an increase in the adjustment amount. By contrast, the write assist circuit 14 of the first embodiment adjusts the assist amount using the inter-wire capacitances Cc1 to CcN, which does not need an increase in the area.

Therefore, it is possible to cope with manufacturing variations and reliability problems after manufacturing without changing the design, and to improve the yield. It is also possible to prevent the assist amount from becoming excessive, which reduces wasteful electric power.

The first wiring 14a including the aggressor wires 14a1 to 14aN and the victim wires 14b1 to 14bN are mounted on a wiring layer above the wiring layer of the memory cell array 11. This further prevents an increase in the area as compared with the write assist circuit that adjusts the assist amount using a capacitive element.

### Second Embodiment

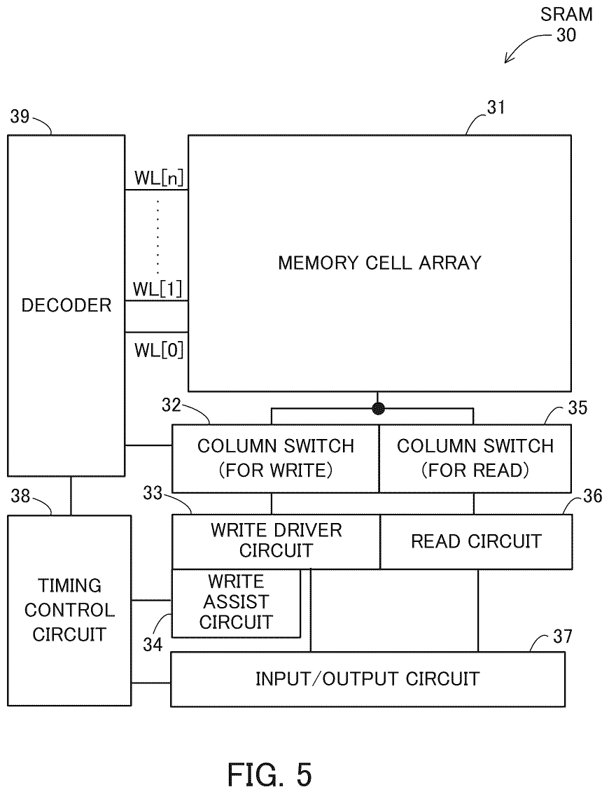

FIG. 5 illustrates an example of the overall configuration of an SRAM according to a second embodiment.

The SRAM 30 includes a memory cell array 31, a write column switch 32, a write driver circuit 33, and a write assist circuit 34. The SRAM 30 further includes a read column switch 35, a read circuit 36, an input/output circuit 37, a timing control circuit 38, and a decoder 39.

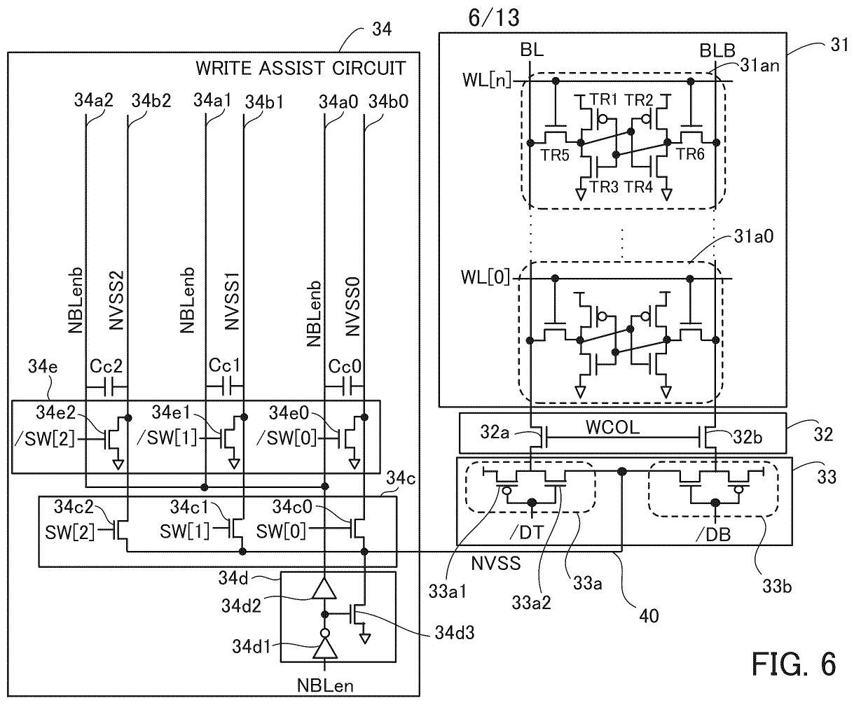

The memory cell array 31 includes a plurality of memory cells arranged in an array. Each memory cell is connected to one of word lines WL[0], WL[1], . . . , and WL[n] and a bit line pair. A specific example of the memory cell array 31 will be described later (see FIG. 6).

At the time of a write operation, the column switch 32 selects any bit line pair of the memory cell array 31 in response to a column selection signal supplied from the decoder 39.

The write driver circuit 33 applies a potential corresponding to write data input from the input/output circuit 37 to the selected bit line pair based on a timing signal output from the timing control circuit 38.

The write assist circuit 34 expands an operation margin for writing to memory cells in order to prevent a deterioration in the write performance.

At the time of a read operation, the column switch 35 selects any bit line pair of the memory cell array 31 in response to a column selection signal supplied from the decoder 39.

The read circuit 36 propagates read data based on the potential of the selected bit line pair to the input/output circuit 37 based on a timing signal output from the timing control circuit 38.

The input/output circuit 37 receives an input of write data from the outside of the SRAM 30 based on a timing signal output from the timing control circuit 38. In addition, the input/output circuit 37 outputs read data to the outside of the SRAM 30 based on a timing signal output from the timing control circuit 38.

The timing control circuit 38 controls the operation timing of each unit of the SRAM 30.

The decoder 39 decodes an address signal input from the outside of the SRAM 30 and determines word lines WL[0] to WL[n] to be activated (H-level potential). In addition, the decoder 39 decodes the address signal to generate a column selection signal.

FIG. 6 illustrates an example of the configuration of the write assist circuit according to the second embodiment. FIG. 6 also illustrates an example of the configuration of the memory cell array 31, the column switch 32, and the write driver circuit 33.

The memory cell array 31 includes memory cells 31a0 to 31an, bit lines BL and BLB, and word lines WL[0] to WL[n]. Each memory cell 31a0 to 31an is connected to the bit lines BL and BLB. The memory cell 31a0 is connected to the word line WL[0]. The memory cell 31an is connected to the word line WL[n]. The word lines WL[0] to WL[n] are connected to the decoder 39.

For example, when write data is written to the memory cell 31a0, the potential of the word line WL[0] becomes H level. When write data is written to the memory cell 31an, the word line WL[n] becomes H level.

Since the configuration of the memory cells 31a0 to 31an is the same as that of the memory cells 11a0 and 11an illustrated in FIG. 3, the description thereof will be omitted.

The column switch 32 includes transistors 32a and 32b. The write driver circuit 33 includes inverter circuits 33a and 33b. In the example of FIG. 6, the transistors 32a and 32b are n-channel MOSFETs. The drain of the transistor 32a is connected to the bit line BL, and the source thereof is connected to the output terminal of the inverter circuit 33a. The drain of the transistor 32b is connected to the bit line BLB, and the source thereof is connected to the output terminal of the inverter circuit 33b. The gates of the transistors 32a and 32b are connected to each other, and a column selection signal WCOL is applied thereto from the decoder 39.

Of complementary write data /DT and /DB, the write data/DT is input to the inverter circuit 33a. Of the complementary write data /DT and /DB, the write data /DB is input to the inverter circuit 33b. The low-potential power supply terminals of the inverter circuits 33a and 33b, which correspond to the low-potential power supply terminal of the write driver circuit 33, are connected to the write assist circuit 34.

The inverter circuit 33a includes transistors 33a1 and 33a2. In the example of FIG. 6, the transistor 33a1 is a p-channel MOSFET, and the transistor 33a2 is an n-channel MOSFET. The source of the transistor 33a1 corresponds to the high-potential power supply terminal of the inverter circuit 33a, and a power supply potential is applied to the source. The drain of the transistor 33a1 is connected to the drain of the transistor 33a2. The drains of the transistors 33a1 and 33a2 correspond to the output terminal of the inverter circuit 33a. The gates of the transistors 33a1 and 33a2 are connected to each other, and the write data /DT is input to each of the gates. The gates of the transistors 33a1 and 33a2 correspond to the input terminal of the inverter circuit 33a. The source of the transistor 33a2 corresponds to the low-potential power supply terminal of the inverter circuit 33a, and the write assist circuit 34 is connected to the source via a wire 40.

Since the configuration of the inverter circuit 33b is the same as that of the inverter circuit 33a, the description thereof will be omitted. In FIG. 6, the potential of the wire 40 connecting the low-potential power supply terminals of the inverter circuits 33a and 33b and the write assist circuit 34 is denoted as “NVSS.”

The write assist circuit 34 includes aggressor wires 34a0, 34a1, and 34a2, victim wires 34b0, 34b1, and 34b2, a selection circuit 34c, a write assist control circuit 34d, and a shorting circuit 34e. In the example of FIG. 6, three aggressor wires 34a0 to 34a2 and three victim wires 34b0 to 34b2 are provided. However, the number of these wires is not limited thereto.

The aggressor wires 34a0 to 34a2 are connected to the write assist control circuit 34d. When the write assist is executed, the potentials NBLenb of the aggressor wires 34a0 to 34a2 are changed from the H level to the L level.

The victim wires 34b0 to 34b2 receive noise in the negative potential direction based on the magnitudes of the inter-wire capacitances from the aggressor wires 34a0 to 34a2 during the write assist operation, and are brought to negative potentials. In the example of FIG. 6, the inter-wire capacitances Cc0, Cc1, and Cc2 are illustrated. The inter-wire capacitance Cc0 is the inter-wire capacitance between the aggressor wire 34a0 and the victim wire 34b0. The inter-wire capacitance Cc1 is the inter-wire capacitance between the aggressor wire 34a1 and the victim wire 34b1. The inter-wire capacitance Cc2 is the inter-wire capacitance between the aggressor wire 34a2 and the victim wire 34b2. In FIG. 6, the potential of the victim wire 34b0 is denoted as “NVSS0,” the potential of the victim wire 34b1 is denoted as “NVSS1,” and the potential of the victim wire 34b2 is denoted as “NVSS2.”

The selection circuit 34c includes switches 34c0, 34c1, and 34c2. In the example of FIG. 6, each of the switches 34c0 to 34c2 is an n-channel MOSFET. One of the source and the drain of the switch 34c0 is connected to the victim wire 34b0. One of the source and the drain of the switch 34c1 is connected to the victim wire 34b1. One of the source and the drain of the switch 34c2 is connected to the victim wire 34b2. A signal SW[0] is input to the gate of the switch 34c0, a signal SW[1] is input to the gate of the switch 34c1, and a signal SW[2] is input to the gate of the switch 34c2. The other of the source and the drain of each of the switches 34c0 to 34c2 is connected to the write assist control circuit 34d and the low-potential power supply terminal of the write driver circuit 33.

When the potential of the signal SW[0] is at H level, the switch 34c0 is turned on, and the victim wire 34b0 is placed in the selected state. When the potential of the signal SW[0] is at L level, the switch 34c0 is turned off, and the victim wire 34b0 is placed in the non-selected state.

When the potential of the signal SW[1] is at H level, the switch 34c1 is turned on, and the victim wire 34b1 is placed in the selected state. When the potential of the signal SW[1] is at L level, the switch 34c1 is turned off, and the victim wire 34b1 is placed in the non-selected state.

When the potential of the signal SW[2] is at H level, the switch 34c2 is turned on, and the victim wire 34b2 is placed in the selected state. When the potential of the signal SW[2] is at L level, the switch 34c2 is turned off, and the victim wire 34b2 is placed in the non-selected state.

Victim wires in the selected state are electrically connected to the low-potential power supply terminal of the write driver circuit 33.

Hereinafter, the signals SW[0] to SW[2] may be collectively referred to as a selection signal SW[2:0]. The selection signal SW[2:0] indicates a selection number indicating how many victim wires 34b0 to 34b2 to select.

The selection signal SW[2:0] is input from the outside of the SRAM 10, for example. For example, the selection signal SW[2:0] is input by a test apparatus at the time of tests after the manufacturing of the SRAM 30. After an appropriate value for the selection signal SW[2:0] is determined, the value of the selection signal SW[2:0] may be fixed by using, for example, a read only memory (ROM).

The write assist control circuit 34d includes an inverter circuit 34d1, a buffer circuit 34d2, and a transistor 34d3.

The inverter circuit 34d1 receives, for example, an enable signal NBLen from the timing control circuit 38.

The output signal of the inverter circuit 34d1 is input to the buffer circuit 34d2. The output potential of the buffer circuit 34d2 serves as the potentials NBLenb of the aggressor wires 34a0 to 34a2.

The transistor 34d3 has a switching function of switching between enabling and disabling the electrical connection between the write driver circuit 33 and the selection circuit 34c. In the example of FIG. 6, the transistor 34d3 is an n-channel MOSFET. The output signal of the inverter circuit 34d1 is input to the gate of the transistor 34d3. The drain of the transistor 34d3 is electrically connected to the selection circuit 34c and the low-potential power supply terminal of the write driver circuit 33. The source of the transistor 34d3 is grounded.

The shorting circuit 34e short-circuits a non-selected victim wire among the victim wires 34b0 to 34b2 to the ground potential in response to the selection signal SW[2:0]. In the example of FIG. 6, the shorting circuit 34e includes switches 34e0, 34e1, and 34e2.

In the example of FIG. 6, each of the switches 34e0 to 34e2 is an n-channel MOSFET. The drain of the switch 34e0 is connected to the victim wire 34b0, the drain of the switch 34e1 is connected to the victim wire 34b1, and the drain of the switch 34e2 is connected to the victim wire 34b2. A signal /SW[0], which is obtained by inverting the polarity of the potential of the signal SW[0] from the H level to the L level or from the L level to the H level, is input to the gate of the switch 34e0. Similarly, a signal /SW[1], which is obtained by inverting the polarity of the potential of the signal SW[1], is input to the gate of the switch 34e1, and a signal /SW[2], which is obtained by inverting the polarity of the potential of the signal SW[2], is input to the gate of the switch 34e2. The sources of the switches 34e0 to 34e2 are grounded.

The write assist circuit 34 may include an inverter circuit that inverts the potential levels of the signals SW[0] to SW[2] and outputs the signals /SW[0] to /SW[2].

Next, an example of the write assist operation of the write assist circuit 34 according to the second embodiment will be described.

When the potential of the enable signal NBLen input from the timing control circuit 38 is at L level, the write assist circuit 34 is brought to an inactive state (a state in which the write assist operation is not performed). At this time, the potential of the output signal of the inverter circuit 34d1 of the write assist control circuit 34d becomes H level, so that the transistor 34d3 is turned on. Therefore, the potential NVSS of the wire 40 becomes the ground potential. Among the victim wires 34b0 to 34b2, victim wires selected by the selection signal SW[2:0] also have the ground potential. The potentials of the aggressor wires 34a0 to 34a2 are at H level when the potential of the output signal of the inverter circuit 34d1 is at H level.

When the potential of the enable signal NBLen becomes H level, the write assist circuit 34 is brought to an active state (a state in which the write assist operation is performed). At this time, the potential of the output signal of the inverter circuit 34d1 of the write assist control circuit 34d becomes L level, so that the transistor 34d3 is turned off. Therefore, the wire 40 and victim wires selected by the selection signal SW[2:0] change from the ground potential state to the floating state. Victim wires that are not selected by the selection signal SW[2:0] are in the ground potential state.

On the other hand, the aggressor wires 34a0 to 34a2 receive a change in the potential of the output signal of the inverter circuit 34d1 via the buffer circuit 34d2. As a result, the potentials of the aggressor wires 34a0 to 34a2 are changed from the H level to the L level.

Due to the above change in the potentials of the aggressor wires 34a0 to 34a2, the victim wires 34b0 to 34b2 receive noise in the negative potential direction based on the magnitudes of the inter-wire capacitances Cc0 to Cc2 due to the capacitive coupling between the wires. As a result, the victim wires 34b0 to 34b2 are brought to negative potentials.

In addition, the wire 40 through which the potential NVSS, which is the output potential of the write assist circuit 34, propagates is also brought to a negative potential due to charge redistribution. The wire 40 is connected to the low-potential power supply terminals of the inverter circuits 33a and 33b of the write driver circuit 33. Therefore, when the potential of the output signal of one of the inverter circuits 33a and 33b becomes L level during a write operation, the potential becomes negative. Of the bit lines BL and BLB, a bit line through which the output signal propagates also has a negative potential. Thus, the write assist is performed with the assist amount (negative potential magnitude) based on the value of the selection signal SW[2:0].

Here, the reason why the shorting circuit 34e is provided will be described below.

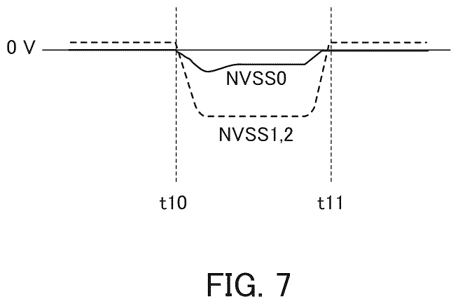

FIG. 7 illustrates an example of changes in the potential of each victim wire during a write assist operation in the case where the shorting circuit is not provided. FIG. 7 illustrates changes in the potentials NVSS0 to NVSS2 of the victim wires 34b0 to 34b2 in the case where the shorting circuit 34e is not provided. Timings t10 to t11 represent a period in which the write assist is performed.

For example, it is assumed that the victim wire 34b0 is in the selected state and the victim wires 34b1 and 34b2 are in the non-selected state. In this case, the victim wires 34b1 and 34b2 in the floating g state may have unexpectedly large negative potentials with respect to the victim wire 34b0 connected to the low-potential power supply terminals of the inverter circuits 33a and 33b of the write driver circuit 33.

As illustrated in FIG. 7, between the timing t10 and the timing t11, the potentials NVSS1 and NVSS2 of the victim wires 34b1 and 34b2 are more greatly shifted to the negative side than the potential NVSS0 of the victim wire 34b0.

When the potentials of non-selected victim wires are greatly shifted to the negative side, the drain-gate voltages of the corresponding switches 34c0 to 34c2, which are n-channel MOSFETs, may exceed a threshold voltage. In this case, the switches 34c0 to 34c2 are not able to maintain the OFF state. This may lead to failing to appropriately control the negative potential magnitude. In addition, since the PN junction portions in the switches 34c0 to 34c2 are forward biased, a latch-up risk may occur if the potentials of the non-selected victim wires are excessively shifted to the negative potential side.

Such a situation is avoided by providing the shorting circuit 34e. When the victim wire 34b0 is in the non-selected state (when the potential of the signal SW [0] is at L level), the potential of the signal /SW [0] is at H level, and thus the switch 34e0 of the shorting circuit 34e is turned on. As a result, the victim wire 34b0 is short-circuited to the ground potential. When the victim wire 34b1 is in the non-selected state (when the potential of the signal SW [1] is at L level), the potential of the signal /SW[1] is at H level, so that the switch 34e1 of the shorting circuit 34e is turned on. As a result, the victim wire 34b1 is short-circuited to the ground potential. When the victim wire 34b2 is in the non-selected state (when the potential of the signal SW [2] is at L level), the potential of the signal /SW [2] is at H level, so that the switch 34e2 of the shorting circuit 34e is turned on. As a result, the victim wire 34b2 is short-circuited to the ground potential.

In this manner, the shorting circuit 34e prevents the potentials of non-selected victim wires from being excessively shifted to the negative potential side by short-circuiting the potentials of the non-selected victim wires to the ground potential.

As with the write assist circuit 14 of the first embodiment, the write assist circuit 34 of the second embodiment as described above is able to adjust the assist amount using the selection signal SW[2:0] even after the manufacturing of the SRAM 30.

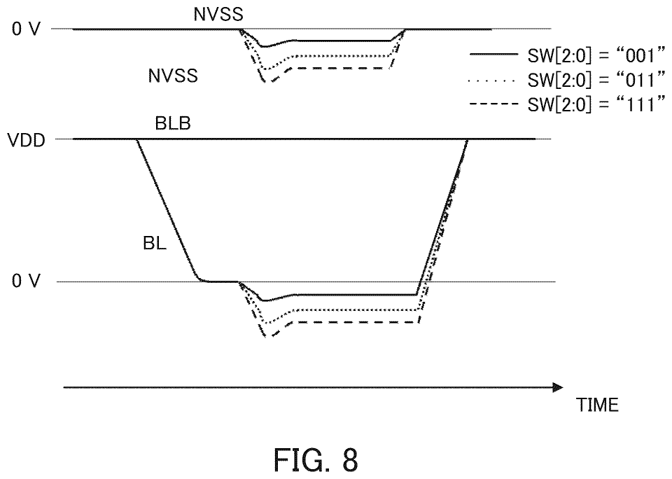

FIG. 8 illustrates an example of temporal changes in the potentials of bit lines in response to the value of the selection signal SW[2:0]. FIG. 8 illustrates temporal changes in the potential NVSS, which is the output potential of the write assist circuit 34, and the potentials of the bit lines BL and BLB in response to the value of the selection signal SW[2:0].

In FIG. 8, SW[2:0]=“001” indicates that the potential of the signal SW[0] is at H level and the potentials of the signals SW[1] and SW[2] are at L level. In this case, the victim wire 34b0 is placed in the selected state, and the victim wires 34b1 and 34b2 are placed in the non-selected state. SW[2:0]=“011” indicates that the potentials of the signals SW[0] and SW[1] are at H level and the potential of the signal SW[2] is at L level. In this case, the victim wires 34b0 and 34b1 are placed in the selected state, and the victim wire 34b2 is placed in the non-selected state. SW[2:0]=“111” indicates that the potentials of the signals SW[0] to SW[2] are at H level. In this case, the victim wires 34b0 to 34b2 are placed in the selected state.

As illustrated in FIG. 8, as the number of victim wires in the selected state increases, the negative potential magnitude, that is, the assist amount increases.

### Process of Adjusting Selection Signal SW[2:0]

Next, a process of adjusting the selection signal SW[2:0] for setting an appropriate assist amount according to the quality of the SRAM 30 after manufacturing will be described. The process of adjusting the selection signal SW[2:0] may automatically be performed by a test apparatus connected to the SRAM 30, for example, at the time of a wafer test of the SRAM 30 or an assembly test after packaging.

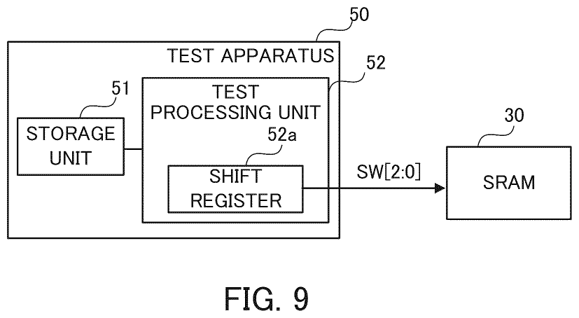

FIG. 9 illustrates an example of a test system. The test system includes the SRAM 30 and a test apparatus 50 connected to the SRAM 30.

The test apparatus 50 includes a storage unit 51 and a test processing unit 52.

The storage unit 51 stores a program for executing a function test and various data used for executing the function test. The storage unit 51 may include a volatile semiconductor memory such as a random access memory (RAM) or may include a non-volatile storage device such as a hard disk drive (HDD) or a flash memory. The storage unit 51 may include both a volatile semiconductor memory and a non-volatile storage device.

The test processing unit 52 executes the function test of the SRAM 30 by executing the program stored in the storage unit 51. In the example of FIG. 9, the test processing unit 52 includes a shift register 52a used for generating the selection signal SW[2:0].

Although not illustrated, the test processing unit 52 may include, for example, a processor such as a central processing unit (CPU), a test pattern generator that generates a test pattern, a timing generator that generates a timing signal, and others.

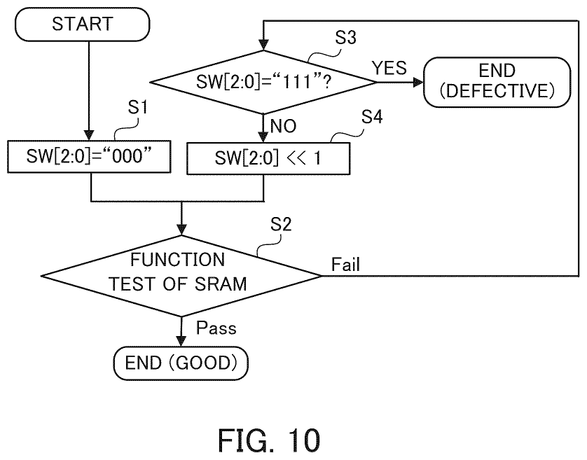

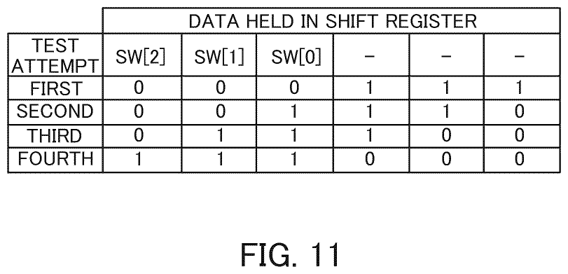

FIG. 10 is a flowchart illustrating an example flow of the process of adjusting the selection signal SW[2:0]. FIG. 11 illustrates an example of data held in the shift register that generates the selection signal SW[2:0].

The shift register 52a of the test apparatus 50 holds, for example, 6-bit data as illustrated in FIG. 11. Then, the shift register 52a outputs the upper three bits as the selection signal SW[2:0].

Step S1: First, the selection signal SW[2:0] is set to “000.”

Step S2: A function test of the SRAM 30 is executed. The function test is executed to test whether the SRAM 30 operates as designed. In the first attempt of the function test, the selection signal SW[2:0] is set to “000” in step S1. Therefore, when a write operation to the SRAM 30 is performed in the function test, all the victim wires are placed in the non-selected state. As a result, the assist amount is 0.

In the case where the SRAM 30 operates as designed, the SRAM 30 is determined to be a “Pass” result and then the process of adjusting the selection signal SW[2:0] is completed. In this case, the SRAM 30 is regarded as a good product. In the case where the SRAM 30 does not operate as designed, the SRAM 30 is determined to be a “Fail” result, and then step S3 is executed. For example, if an expected value is not appropriately written in the SRAM 30, the SRAM 30 is determined to be a “Fail” result. In this case, there is a possibility that the assist amount of the write assist circuit 34 is insufficient.

Step S3: The test apparatus 50 determines whether the selection signal SW[2:0] is “111” indicating that all the victim wires are selected. If it is determined that the selection signal SW[2:0] is “111,” the assist amount setting process is completed. In this case, the SRAM 30 is regarded as a defective product. If it is determined that the selection signal SW[2:0] is not “111,” step S4 is executed.

Step S4: The test apparatus 50 shifts the data held in the shift register 52a to the left. Thereafter, step S2 is executed again.

As illustrated in FIG. 11, when the data held in the shift register 52a is “000111” in the first attempt of the function test, the held data becomes “001110” by being shifted to the left. The selection signal SW[2:0]=“001,” which is the upper three bits of the data, is used in the second attempt of the function test. When a write operation is performed in the second attempt of the function test, the victim wire 34b0 is placed in the selected state, and the assist amount increases from that in the first attempt of the function test.

When the data held in the shift register 52a is “001110” in the second attempt of the function test, the held data becomes “011100” by being shifted to the left. The selection signal SW[2:0]=“011,” which is the upper three bits of the data, is used in the third attempt of the function test. When a write operation is performed in the third attempt of the function test, the victim wires 34b0 and 34b1 are placed in the selected state, and the assist amount increases from that in the second attempt of the function test.

When the data held in the shift register 52a is “011100” in the third attempt of the function test, the held data becomes “111000” by being shifted to the left. The selection signal SW[2:0]=“111,” which is the upper three bits of the data, is used in the fourth attempt of the function test. When a write operation is performed in the fourth attempt of the function test, the victim wires 34b0 to 34b2 are placed in the selected state, and the assist amount increases from that in the third attempt of the function test.

In this manner, by executing the function test while increasing the assist amount stepwise from the minimum assist amount, it is possible to prevent an excessive voltage from being applied to the memory cells 31a0 to 31an and the transistors of the write assist circuit 34. This makes it possible to set an appropriate assist amount from the viewpoint of reliability and power consumption.

### Modifications

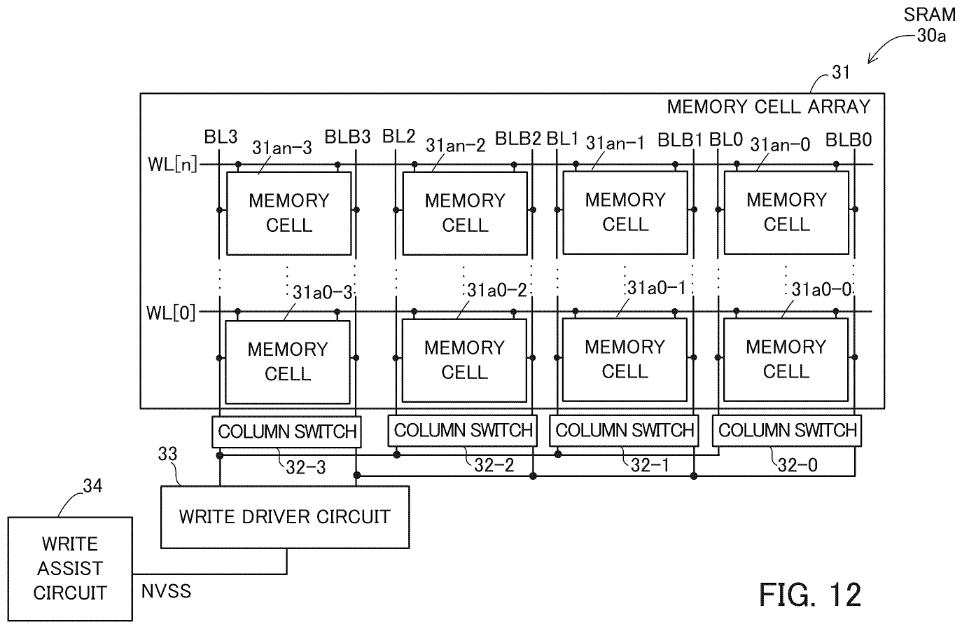

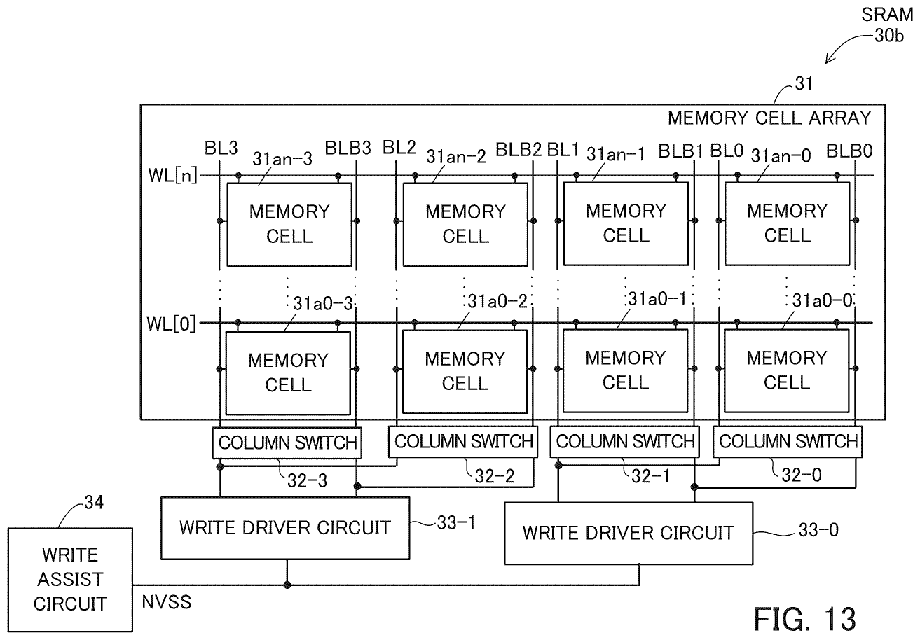

FIG. 12 illustrates an SRAM according to a first modification. In FIG. 12, the same elements as those illustrated in FIG. 6 are denoted by the same reference numerals.

FIG. 6 illustrates the configuration in which one write driver circuit 33 is provided for one column of memory cells. The configuration, however, is not limited thereto. The SRAM 30a illustrated in FIG. 12 is configured so that one write driver circuit 33 is provided in common for a plurality of columns (four columns in FIG. 12) of memory cells.

Memory cells 31a0-0 to 31an-0 are connected to the write driver circuit 33 via bit lines BL0 and BLB0 and a column switch 32-0. Memory cells 31a0-1 to 31an-1 are connected to the write driver circuit 33 via bit lines BL1 and BLB1 and a column switch 32-1. Memory cells 31a0-2 to 31an-2 are connected to the write driver circuit 33 via bit lines BL2 and BLB2 and a column switch 32-2. Memory cells 31a0-3 to 31an-3 are connected to the write driver circuit 33 via bit lines BL3 and BLB3 and a column switch 32-3.

Each of the column switches 32-0 to 32-3 is able to select a memory cell column independently in response to a column selection signal.

During a write operation of the SRAM 30a, the write driver circuit 33 lowers the potential of one of the bit lines BL0 to BL3 or one of the bit lines BLB0 to BLB3 to a negative potential according to the assist amount generated by the write assist circuit 34.

FIG. 13 illustrates an SRAM according to a second modification. In FIG. 13, the same elements as those illustrated in FIGS. 6 and 12 are denoted by the same reference numerals.

FIG. 6 illustrates the configuration in which one write assist circuit 34 is provided for one write driver circuit 33. The configuration, however, is not limited thereto. The SRAM 30b illustrated in FIG. 13 is configured so that one write assist circuit 34 is provided in common for a plurality of (two in FIG. 13) write driver circuits 33-0 and 33-1.

The write driver circuit 33-0 is connected to bit lines BL0 and BLB0 via a column switch 32-0. The write driver circuit 33-0 is also connected to bit lines BL1 and BLB1 via a column switch 32-1.

The write driver circuit 33-1 is connected to bit lines BL2 and BLB2 via a column switch 32-2. The write driver circuit 33-1 is also connected to bit lines BL3 and BLB3 via a column switch 32-3.

During a write operation of the SRAM 30b, the write driver circuits 33-0 and 33-1 lower the potentials of the bit lines BL0 to BL3 or the bit lines BLB0 to BLB3 to negative potentials according to the assist amount generated by the write assist circuit 34.

In the case where one write assist circuit 34 is connected to the write driver circuits 33-0 and 33-1, there is a possibility that, even in the case where the same selection signal SW[2:0] is used, the assist amount (negative potential magnitude) is reduced compared to the case where one write assist circuit 34 is connected to one write driver circuit 33. In this case, the selection signal SW[2:0] that selects a large number of victim wires compared to the case where one write assist circuit 34 is connected to one write driver circuit 33 may be applied to the write assist circuit 34.

One aspect of the write assist circuit and the SRAM has been described above in the embodiments. However, these are merely examples and are not limited to the above description.

In one aspect, it is possible to appropriately adjust the assist amount of a write assist circuit on the basis of the quality of an SRAM after manufacturing.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A write assist circuit for a static random access memory, the write assist circuit comprising:
a first wiring;
a plurality of second wirings configured to receive noise in a negative potential direction from the first wiring; and
a selection circuit configured to select a first number of second wirings from the plurality of second wirings in response to an input selection signal and output a potential of a negative potential magnitude based on a negative potential applied to the first number of second wirings due to the noise.

2. The write assist circuit according to claim 1, wherein
the first wiring includes a plurality of wiring parts arranged in a same direction as a wiring direction of the plurality of second wirings, and
each of the plurality of wiring parts is arranged adjacent to one of the plurality of second wirings at a shorter distance than to other second wirings.

3. The write assist circuit according to claim 1, wherein the selection circuit outputs the potential the negative potential magnitude of which increases as the selected first number of second wirings increases.

4. The write assist circuit according to claim 1, wherein the selection circuit electrically connects the selected first number of second wirings to a low-potential power supply terminal of a write driver circuit of the static random access memory.

5. The write assist circuit according to claim 1, further comprising a shorting circuit configured to short-circuit, to a ground potential, a second wiring placed in a non-selected state among the plurality of second wirings in response to the selection signal.

6. The write assist circuit according to claim 1, wherein the first number is an integer of 0 or more.

7. The write assist circuit according to claim 1, wherein the negative potential magnitude is adjusted by increasing the first number one by one from 0 in response to the selection signal.

8. A static random access memory comprising:
a memory cell array including a memory cell connected to a first bit line and a second bit line;
a write driver circuit configured to apply different potentials to the first bit line and the second bit line in a write operation to the memory cell; and
a write assist circuit connected to the write driver circuit;
wherein the write assist circuit includes
a first wiring,
a plurality of second wirings configured to receive noise in a negative potential direction from the first wiring, and
a selection circuit configured to select a first number of second wirings from the plurality of second wirings in response to an input selection signal and output, to the write driver circuit, a potential of a negative potential magnitude based on a negative potential applied to the first number of second wirings due to the noise.
